(19) United States
(12) Patent Application Publication
(10) Pub. No.: US 2008/0304303 A1
(43) Pub. Date: Dec. 11, 2008

(54) POWER CONVERTING DEVICE

(75) Inventors: Fang-Ming Hsieh, Taipei City (TW); Shih-Yao Lin, Taipei City (TW)

Correspondence Address: BROOKS KUSHMAN P.C., 1000 TOWN CENTER, TWENTY-SECOND FLOOR, SOUTHFIELD, MI, 48075, US

(73) Assignee: WORLD FRIENDSHIP CO., LTD., Taipei City (TW)

(21) Appl. No.: 11/758,585

(22) Filed: Jun. 5, 2007

(51) Int. Cl. H05K 7/20; H02H 7/125

(52) U.S. Cl. 363/141; 363/52

(57) ABSTRACT

A power converting device includes a power converting unit for converting an AC voltage input into a DC voltage output, a cooling fan for dissipating heat generated by the power converting unit, a detecting unit connected electrically to the power converting unit for detecting a current output of the power converting unit and for generating a control signal corresponding to the current output detected thereby, and a controller connected electrically to the cooling fan and the detecting unit for controlling rotational speed of the cooling fan in accordance with the control signal from the detecting unit.

### BACKGROUND OF THE INVENTION

1. Field of the Invention

The invention relates to a power converting device, more particularly to a power converting device adapted for use in a recreational vehicle.

2. Description of the Related Art

FIG. 1 illustrates a conventional power converting device 1 disclosed in U.S. Patent Application Publication No. US 2006/0083031. The conventional power converting device 1 includes an AC-to-DC rectifier circuit 11, a controller 12, a switch circuit 13, a transformer circuit 14, an LC filter 15, a voltage feedback circuit 16, a fan 17, a fan control circuit 18, an over-temperature shutdown circuit 19, and a thermistor circuit 10, wherein the thermistor circuit 10 senses temperature of a heat sink, and generates a signal corresponding to the temperature of the heat sink sensed thereby. The fan control circuit 18 controls rotational speed of the fan 17 in accordance with the signal from the thermistor circuit 10 such that the rotational speed of the fan 17 increases in response to increase in the sensed temperature of the heat sink.

However, in the conventional power converting device 1, even though the temperature of the heat sink is within a low temperature range, the fan 17 is controlled by the fan control circuit 18 to operate at a corresponding low rotational speed such that low fan noise effect in response to low rotational speed operation of the fan 17 occurs.

### SUMMARY OF THE INVENTION

Therefore, the object of the present invention is to provide a power converting device that can ensure safe operation with relatively low fan noise effect.

According to the present invention, a power converting device comprises:

a power converting unit for converting an AC voltage input into a DC voltage output;

a cooling fan for dissipating heat generated by the power converting unit;

a detecting unit connected electrically to the power converting unit for detecting a current output of the power converting unit and for generating a control signal corresponding to the current output detected thereby; and

a controller connected electrically to the cooling fan and the detecting unit for controlling rotational speed of the cooling fan in accordance with the control signal from the detecting unit.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic circuit block diagram of a conventional power converting device;

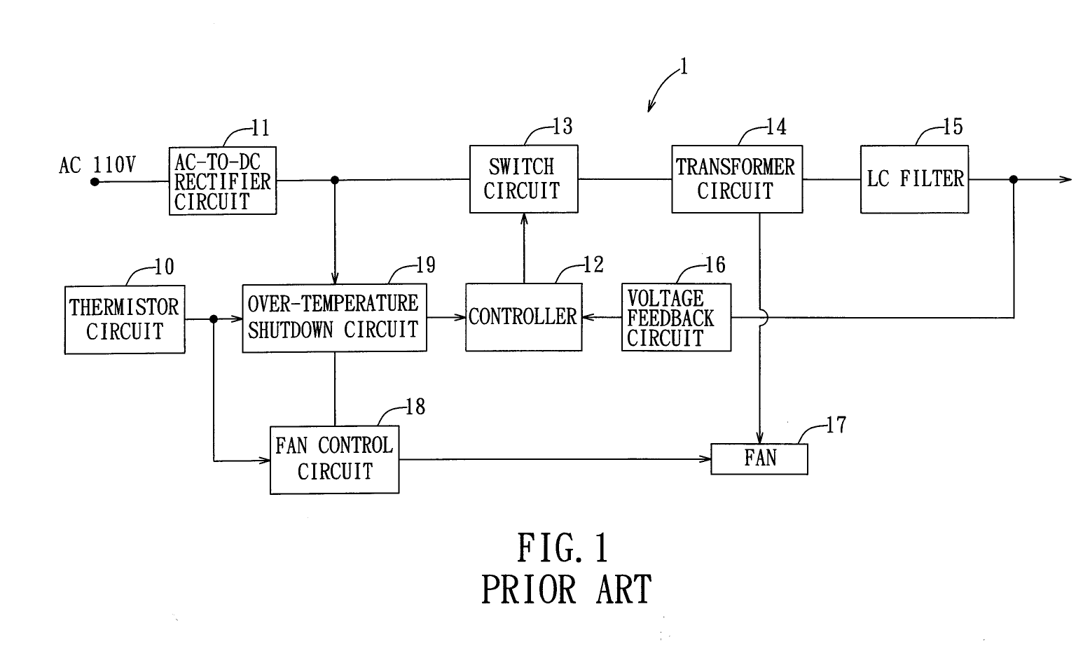

FIG. 2 is a schematic circuit block diagram showing the first preferred embodiment of a power converting device according to the present invention;

FIG. 3 is a plot illustrating the relationship between rotational speed of a cooling fan and a current output of a power converting unit in the first preferred embodiment;

FIG. 4 is a schematic circuit block diagram showing the second preferred embodiment of a power converting device according to the present invention;

FIG. 5 is a plot illustrating the relationship between rotational speed of a cooling fan, and a current output and temperature of a power converting unit in the second preferred embodiment; and

FIG. 6 is a plot illustrating the relationship between the rotational speed of the cooling fan and the temperature of the power converting unit in the second preferred embodiment.

### DETAILED DESCRIPTION OF THE PREFERRED EMBODIMENTS

Before the present invention is described in greater detail, it should be noted that like elements are denoted by the same reference numerals throughout the disclosure.

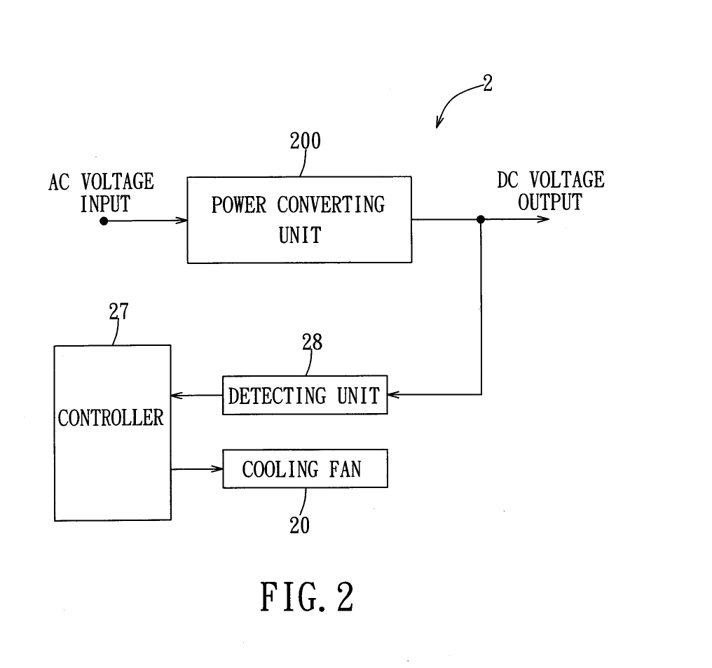

Referring to FIG. 2, the first preferred embodiment of a power converting device 2 according to the present invention is shown to include a power converting unit 200, a cooling fan 20, a detecting unit 28, and a controller 27. The power converting device 2 is adapted for use in a recreational vehicle as a DC power supply or a battery changer.

The power converting unit 200 converts an AC voltage input, such as AC 100V, into a DC voltage output, such as DC 13.6V, that is adapted to be supplied to an external load device (not shown). Since the feature of the present invention does not reside in the power converting unit 200, which is known to those skilled in the art, further details of the same are omitted therein for sake of brevity. An example of the power converting unit 200 suitable for application in this invention is described in US 2006/008031, the entire disclosure of which is incorporated herein by reference.

The cooling fan 20 dissipates heat generated by the power converting unit 200.

The detecting unit 28 is connected electrically to the power converting unit 200 for detecting a current output (or load current) of the power converting unit 200 and for generating a control signal corresponding to the current output detected thereby. In this embodiment, the control signal is a voltage signal having a linear proportion relation with the current output of the power converting unit 200.

The controller 27 is connected electrically to the cooling fan 20 and the detecting unit 28 for controlling rotational speed of the cooling fan 20 in accordance with the control signal from the detecting unit 28.

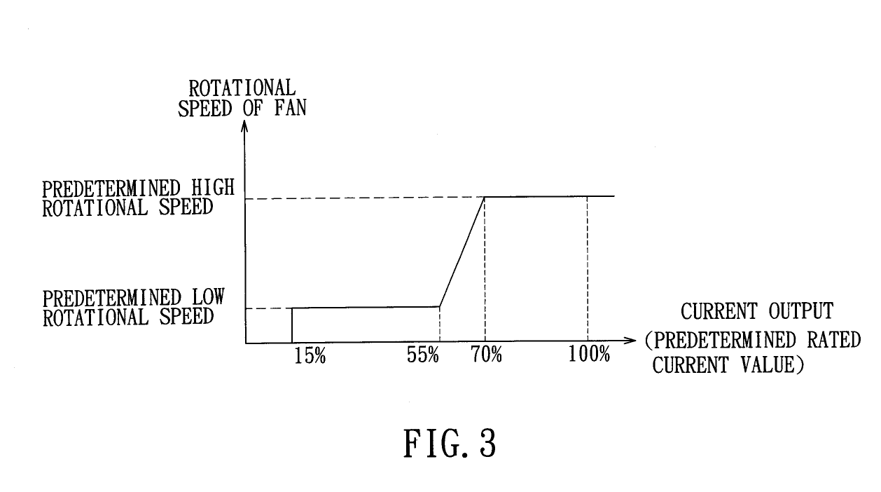

Referring to FIG. 3, in this embodiment, how the cooling fan 20 is controlled by the controller 27 in accordance with the control signal from the detecting unit 28 is described in detail as follows.

The controller 27 controls the cooling fan 20 to shut down upon detection that the current output of the power converting unit 200 is smaller than 15% of a predetermined rated current value. In this case, the power converting device 2 is operated in a low load state without fan noise effect.

The controller 27 controls the cooling fan 20 to operate at a predetermined low rotational speed using known PWM control techniques upon detection that the current output of the power converting unit 200 is within a range of 15%˜55% of the predetermined rated current value. In this case, the power converting device 2 is operated in a medium load state with relatively low fan noise effect.

The controller 27 controls the cooling fan 20 to operate at a variable rotational speed changeable with the current output of the power converting unit 200 (i.e., the rotational speed is proportional to the current output of the power converting unit 200) using known PWM control techniques upon detection that the current output of the power converting unit 200 is within a range of 55%˜70% of the predetermined rated current value. In this case, in order to ensure heat dissipation of the power converting unit 200 as a result of a high load output, the rotational speed of the cooling fan 20 is varied with the current output of the power converting unit 200 such that the power converting device 2 can be safely operated with dynamically adjusted fan noise effect.

The controller 27 controls the cooling fan 20 to operate at a predetermined high rotational speed using known PWM control techniques upon detection that the current output of the power converting unit 200 is greater than 70% of a predetermined rated current value, thereby ensuring fast heat dissipation.

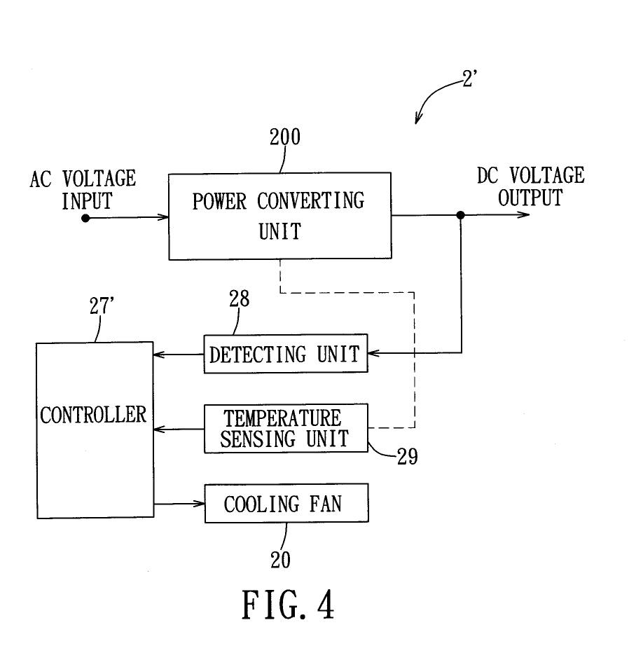

FIG. 4 illustrates the second preferred embodiment of a power converting device 2′ according to this invention, which is a modification of the first preferred embodiment. In this embodiment, the power converting device 2′ further includes a temperature sensing unit 29 connected electrically to the controller 27′ for sensing temperature of the power converting unit 200 and for outputting a temperature signal corresponding to the temperature of the power converting unit 200 to the controller 27′. In this embodiment, the temperature sensing unit 29 is a negative temperature coefficient variable resistor, such as a thermistor or a resistance temperature detector. The controller 27′ further controls the rotational speed of the cooling fan 20 in accordance with the temperature signal from the temperature sensing unit 29.

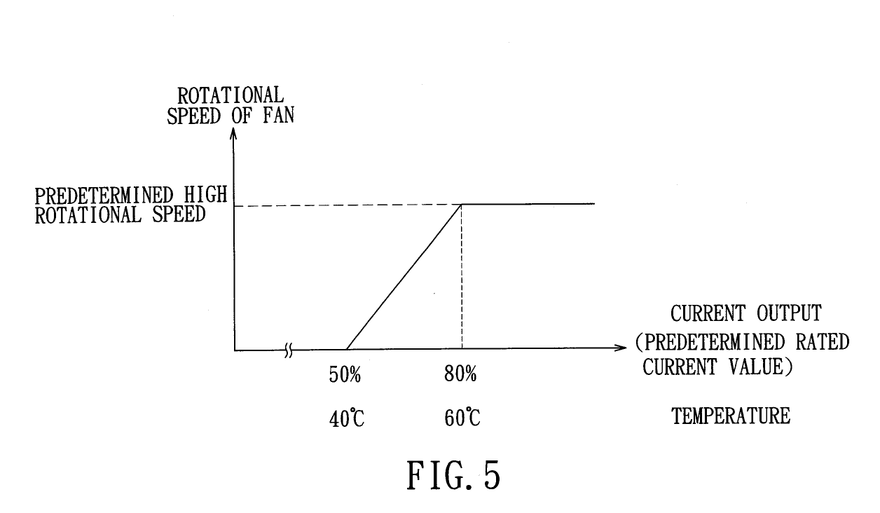

Referring to FIG. 5, in this embodiment, how the cooling fan 20 is controlled by the controller 27′ in accordance with the control signal from the detecting unit 28 and the temperature signal from the temperature sensing unit 29 is described in detail as follows.

The controller 27′ controls the cooling fan 20 to shut down upon detection that the current output of the power converting unit is smaller than 50% of the predetermined rated current value and that the temperature of the power converting unit 200 is lower than 40° C.

The controller 27′ controls the cooling fan 20 to operate at a variable rotational speed changeable with the temperature of the power converting unit 200 (i.e., the rotational speed of the cooling fan 20 is proportional to the temperature of the power converting unit 200) using known PWM control techniques upon detection that the current output of the power converting unit 200 is within a range of 50%˜80% of the predetermined rated current value and that the temperature of the power converting unit 200 is higher than 40° C.

The controller 27′ controls the cooling fan 200 to operate at the predetermined high rotational speed using known PWM control techniques upon detection that the current output of the power converting unit 200 is greater than 80% of the predetermined rated current value and that the temperature of the power converting unit 200 is higher than 60° C.

On the other hand, the controller 27′ can also control the rotational speed of the cooling fan 20 in accordance with the temperature signal from the temperature sensing unit 29 independent of the current output of the power converting unit 200.

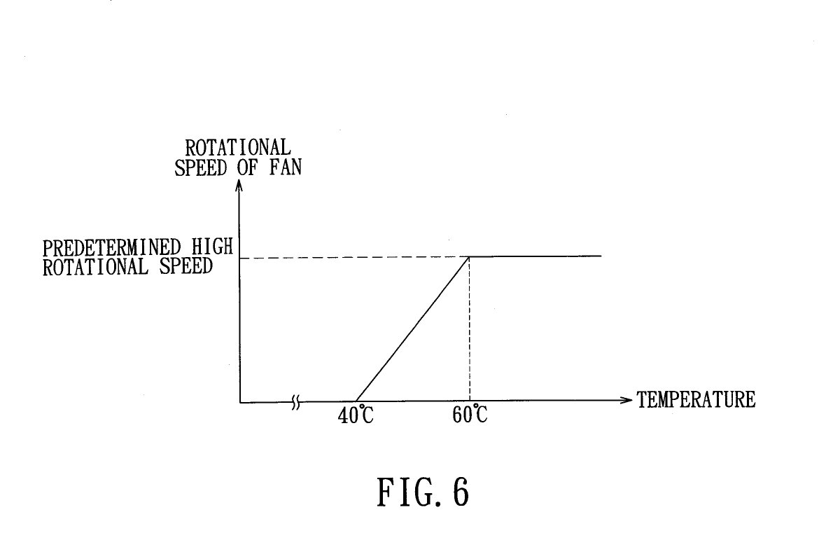

Referring to FIG. 6, in this embodiment, how the cooling fan 20 is controlled by the controller 27′ in accordance with the temperature signal from the temperature sensing unit 29 is described in detail as follows.

The controller 27′ controls the cooling fan 200 to shut down upon detection that the temperature of the power converting unit 200 is lower than 40° C.

The controller 27′ controls the cooling fan 200 to operate at a variable rotational speed changeable with the temperature of the power converting unit 200 (i.e., the rotational speed of the cooling fan 20 is proportional to the temperature of the power converting unit 200) using known PWM control techniques upon detection that the temperature of the power converting unit 200 is within a range of 40° C.˜60° C.

The controller 27′ controls the cooling fan 200 to operate at the predetermined high rotational speed using known PWM control techniques upon detection that the temperature of the power converting unit 200 is higher than 60° C.

In sum, due to the presence of the detecting unit 28 and the temperature sensing unit 29, the controller 27, 27′ can appropriately control the rotational speed of the cooling fan 20 in accordance with at least one of the current output and the temperature of the power converting unit 200. In particular, when the temperature of the power converting unit 200 is lower than 40° C. and when the current output of the power converting unit 200 is smaller than 15% of the predetermined rated current value, the cooling fan 20 is shut down so that no fan noise is generated during low load conditions.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A power converting device comprising:
a power converting unit for converting an AC voltage input into a DC voltage output;
a cooling fan for dissipating heat generated by said power converting unit;
a detecting unit connected electrically to said power converting unit for detecting a current output of said power converting unit and for generating a control signal corresponding to the current output detected thereby; and
a controller connected electrically to said cooling fan and said detecting unit for controlling rotational speed of said cooling fan in accordance with the control signal from said detecting unit.

2. The power converting device as claimed in claim 1, wherein said controller controls said cooling fan to shut down in accordance with the control signal from said detecting unit upon detection that the current output of said power converting unit is smaller than 15% of a predetermined rated current value.

3. The power converting device as claimed in claim 1, wherein said controller controls said cooling fan to operate at a predetermined low rotational speed in accordance with the control signal from said detecting unit upon detection that the current output of said power converting unit is within a range of 15%˜55% of a predetermined rated current value.

4. The power converting device as claimed in claim 1, wherein said controller controls said cooling fan to operate at a variable rotational speed changeable with the current output of said power converting unit in accordance with the control signal from said detecting unit upon detection that the current output of said power converting unit is within a range of 55%˜70% of a predetermined rated current value.

5. The power converting device as claimed in claim 1, wherein said controller controls said cooling fan to operate at a predetermined high rotational speed in accordance with the control signal from said detecting unit upon detection that the current output of said power converting unit is greater than 70% of a predetermined rated current value.

6. The power converting device as claimed in claim 1, further comprising a temperature sensing unit connected electrically to said controller for sensing temperature of said power converting unit and for outputting a temperature signal corresponding to the temperature of said power converting unit to said controller, said controller further controlling the rotational speed of said cooling fan in accordance with the temperature signal from said temperature sensing unit.

7. The power converting device as claimed in claim 6, wherein said controller controls said cooling fan to shut down in accordance with the temperature signal from said temperature sensing unit upon detection that the temperature of said power converting unit is lower than 40° C.

8. The power converting device as claimed in claim 6, wherein said controller controls said cooling fan to operate at a variable rotational speed changeable with the temperature of said power converting unit in accordance with the temperature signal from said temperature sensing unit upon detection that the temperature of said power converting unit is within a range of 40° C.˜60° C.

9. The power converting device as claimed in claim 6, wherein said controller controls said cooling fan to operate at a predetermined high rotational speed in accordance with the temperature signal from said temperature sensing unit upon detection that the temperature of said power converting unit is higher than 60° C.

10. The power converting device as claimed in claim 6, wherein said controller controls said cooling fan to shut down in accordance with the control signal from said detecting unit and the temperature signal from said temperature sensing unit upon detection that the current output of said power converting unit is smaller than 50% of a predetermined rated current value and that the temperature of said power converting unit is lower than 40° C.

11. The power converting device as claimed in claim 6, wherein said controller controls said cooling fan to operate at a variable rotational speed changeable with the temperature of said power converting unit in accordance with the control signal from said detecting unit and the temperature signal from said temperature sensing unit upon detection that the current output of said power converting unit is within a range of 50%˜80% of a predetermined rated current value and that the temperature of said power converting unit is higher than 40° C.

12. The power converting device as claimed in claim 6, wherein said controller controls said cooling fan to operate at a predetermined high rotational speed in accordance with the control signal from said detecting unit and the temperature signal from said temperature sensing unit upon detection that the current output of said power converting unit is greater than 80% of a predetermined rated current value and that the temperature of said power converting unit is higher than 60° C.
